(19) United States
(12) Patent Application Publication
(10) Pub. No.: US 2016/0197092 A1
(43) Pub. Date: Jul. 7, 2016

(54) VERTICAL MEMORY DEVICES AND RELATED METHODS OF MANUFACTURE

(71) Applicant: Macronix International Co., Ltd., Hsinchu (TW)

(72) Inventor: Shih-Ping Hong, Zhubei City (TW)

(21) Appl. No.: 14/590,081

(22) Filed: Jan. 6, 2015

(51) Int. Cl. H01L 27/115; H01L 23/528; H01L 29/06

(52) U.S. Cl. CPC H01L 27/11582; H01L 27/11568; H01L 29/0653; H01L 23/528

(57) ABSTRACT

A vertical semiconductor memory device having conducting and charge-trapping columns separated by columns of holes is disclosed. The columns are formed in layers of alternating conducting and insulating material with the conducting/charge-trapping columns and columns of holes separating layers of conducting material into disjoint strips. The conducting columns and separated layers of conducting material form wordlines and bitlines in the device.

### BACKGROUND OF THE INVENTION

1. Field of the Invention

The present invention relates generally to semiconductor fabrication methods and, more particularly, to fabrication of vertical memory devices.

2. Description of Related Art

As densities of semiconductor memories increase, two-dimensional structures are no longer able to meet specified requirements. Accordingly, three-dimensional memories are becoming known, although manufacturing processes for three-dimensional memories pose special problems. FIG. 1 is a cross-section of a semiconductor device 100 illustrating an example of registration/alignment of three-dimensional stacked structures having bending and wiggling of line boundaries created by line patterning. These difficulties are especially severe when high aspect ratios are involved. For example, vertical elements, such as line separation structures 105, when viewed at a cross-section A-A′ in FIG. 1, may exhibit proper separation suitable for filling spaces 110 with conductive and/or other material. When viewed at cross-section B-B′, however, the effect of bending and wiggling is evident. Vertical direction stringers (undesired connections between conducting elements/layers) may also occur in similar cross-sections. These manufacturing problems complicate efforts to fabricate three-dimensional memory devices with cells having a sufficiently small size (hence achieving high memory densities) to meet ever more stringent requirements.

A need thus exists in the prior art for a method of memory cell manufacture that avoids the stringer and bending/wiggling issues. A further need exists for a method of reliably fabricating memory cells with very small sizes.

### SUMMARY OF THE INVENTION

The present invention addresses these needs by providing a three-dimensional semiconductor memory device comprising a plurality of alternating layers of conducting material and insulating material overlying a substrate. A plurality of first holes in the alternating layers are disposed in first rows, wherein the first holes are lined with information storage film, and the lined first holes are filled with conducting material that form conducting columns. A plurality of isolation holes are disposed in the alternating layers between and linking adjacent first holes in the first rows. The device further includes a plurality of column connectors that connect conducting columns in second rows, the second rows crossing the first rows at an angle.

According to one example of the invention herein disclosed, the first holes are disposed in parallel rows and the second rows cross the first rows at an angle that is or is not a right angle. Choosing the angle to be about 60° reduces the size of a memory cell in the semiconductor device to about 86.6% of the size of a memory cell in the semiconductor device in which an angle of about 90° is chosen.

According to another example, the conducting columns comprise wordlines defining a vertical gate memory device, whereas in another example, the conducting columns comprise bitlines defining a vertical channel memory device.

While the invention has been and/or will be described for the sake of grammatical fluidity with functional explanations, it is to be expressly understood that the claims, unless indicated otherwise, are not to be construed as limited in any way by the construction of “means” or “steps” limitations, but are to be accorded the full scope of the meaning and equivalents of the definition provided by the claims under the judicial doctrine of equivalents.

Any feature or combination of features described or referenced herein are included within the scope of the present invention provided that the features included in any such combination are not mutually inconsistent as will be apparent from the context, this specification, and the knowledge of one skilled in the art. In addition, any feature or combination of features described or referenced may be specifically excluded from any embodiment of the present invention. For purposes of summarizing the present invention, certain aspects, advantages and novel features of the present invention are described or referenced. Of course, it is to be understood that not necessarily all such aspects, advantages or features will be embodied in any particular implementation of the present invention. Additional advantages and aspects of the present invention are apparent in the following detailed description and claims that follow.

### BRIEF DESCRIPTION OF THE DRAWINGS

FIG. 1 is a cross-section of a vertical memory line pattern illustrating bending and wiggling, as in the prior art;

FIG. 2 is a top view of a vertical memory structure with first holes formed as disclosed herein;

FIG. 2AB is a cross-sectional view of the structure of FIG. 2 taken along either/both of a line A-A′ and/or along a line B-B′ in FIG. 2 illustrating placement of insulating and conducting layers alternated in the structure and showing cross-sections of the first holes;

FIG. 2CD is a cross-sectional view of the structure of FIG. 2 taken between first holes along either/both of a line C-C′ and/or along a line D-D′ in FIG. 2 further illustrating alternating insulating and conducting layers in the structure;

FIG. 2E shows detail of the structure of FIG. 2 taken from a region E shown dashed in FIG. 2;

FIG. 3 is a cross-sectional view taken along a line G-G′ in FIG. 2CD of a conducting layer in the vertical memory structure of FIG. 2 after lining with storage films and filling-in with conductive material;

FIG. 3AB is a cross-sectional view of the structure of FIG. 3 taken along either/both a line A-A′ and/or along a line B-B′ in FIG. 3 showing conducting columns;

FIG. 3CD is a cross-sectional view of the structure of FIG. 3 taken along either/both of a line C-C′ and/or along a line D-D′ FIG. 3;

FIG. 3E shows detail of first holes lined with storage film and filled-in with conductive material in the structure of FIG. 3;

FIG. 4 is a cross-sectional view taken along a line G-G′ in FIG. 3CD of a conducting layer in the vertical memory structure of FIG. 3 after formation of isolation holes;

FIG. 4A is a cross-sectional view of the structure of FIG. 4 taken along a line A-A′ in FIG. 4;

FIG. 4D is a cross-sectional view of the structure of FIG. 4 taken along a line D-D′ FIG. 4;

FIG. 4E shows detail of the layout of the isolation holes in the structure of FIG. 4;

FIG. 5 is a top view of the hole arrangement in the vertical memory structure of FIG. 4 after patterning and etching to form column connectors;

FIG. 5C is a cross-sectional view of the structure of FIG. 5 taken along a line C-C′ FIG. 5 after formation of column connectors;

FIG. 5D is a cross-sectional view of the structure of FIG. 5 taken along a line D-D′ FIG. 5 after formation of column connectors;

FIG. 5E shows detail of the placement of patterning for formation of column connectors in the structure of FIG. 5;

FIG. 6 is a perspective view of the unit cell structure of a vertical memory device;

FIG. 6A is a cut-away view of the structure of FIG. 6 from a different perspective;

FIG. 7 shows perspective views (A), (B) and (C) of a memory device fabricated according to the present disclosure;

FIG. 8A defines dimensions of an alternative arrangement of first holes in the structure of FIG. 2;

FIG. 8B is a graph quantifying a relationship of parameters of first hole placement according to the alternative hole arrangement of FIG. 8A;

FIG. 9 is a top view of a vertical memory structure showing column connector patterning corresponding to the arrangement of first holes shown in FIG. 8A;

FIG. 10 illustrates detail of a pattern for wordline connectors according to the alternative hole arrangement of FIG. 9;

FIG. 11A is a sketch of a hole cross-section having a bit line surrounded by storage film;

FIG. 11B is a chart describing E-field enhancement in an example disclosed herein;

FIG. 12 illustrates a collection of alternative first hole shapes applicable to the structure of FIG. 2;

FIG. 13A is a reference diagram for FIGS. 13B and 13C;

FIG. 13B is a perspective diagram of a vertical gate memory cell created according to the present disclosure;

FIG. 13C is a perspective diagram of a vertical gate memory cell having a fin-FET-like architecture that implements an aspect of the present disclosure;

FIG. 13D is a reference diagram for FIG. 13E;

FIG. 13E is a perspective diagram of a vertical channel memory cell fabricated according to the present disclosure; and

FIG. 14 is a flow chart summarizing an implementation of a method of manufacture according to the present disclosure.

### DETAILED DESCRIPTION OF THE INVENTION

Examples of the invention are now described and illustrated in the accompanying drawings, instances of which are to be interpreted to be to scale in some implementations while in other implementations, for each instance, not. In certain aspects, use of like or the same reference designators in the drawings and descriptions refers to the same, similar or analogous components and/or elements, while according to other implementations the same use should not. According to certain implementations, use of directional terms, such as, top, bottom, left, right, up, down, over, above, below, beneath, rear, and front, are to be construed literally, while in other implementations the same use should not. The present invention may be practiced in conjunction with various integrated circuit fabrication and other techniques that are conventionally used in the art, and only so much of the commonly practiced process steps are included herein as are necessary to provide an understanding of the present invention. The present invention has applicability in the field of semiconductor devices and processes in general. For illustrative purposes, however, the following description pertains to three-dimensional memory devices and related methods of manufacture.

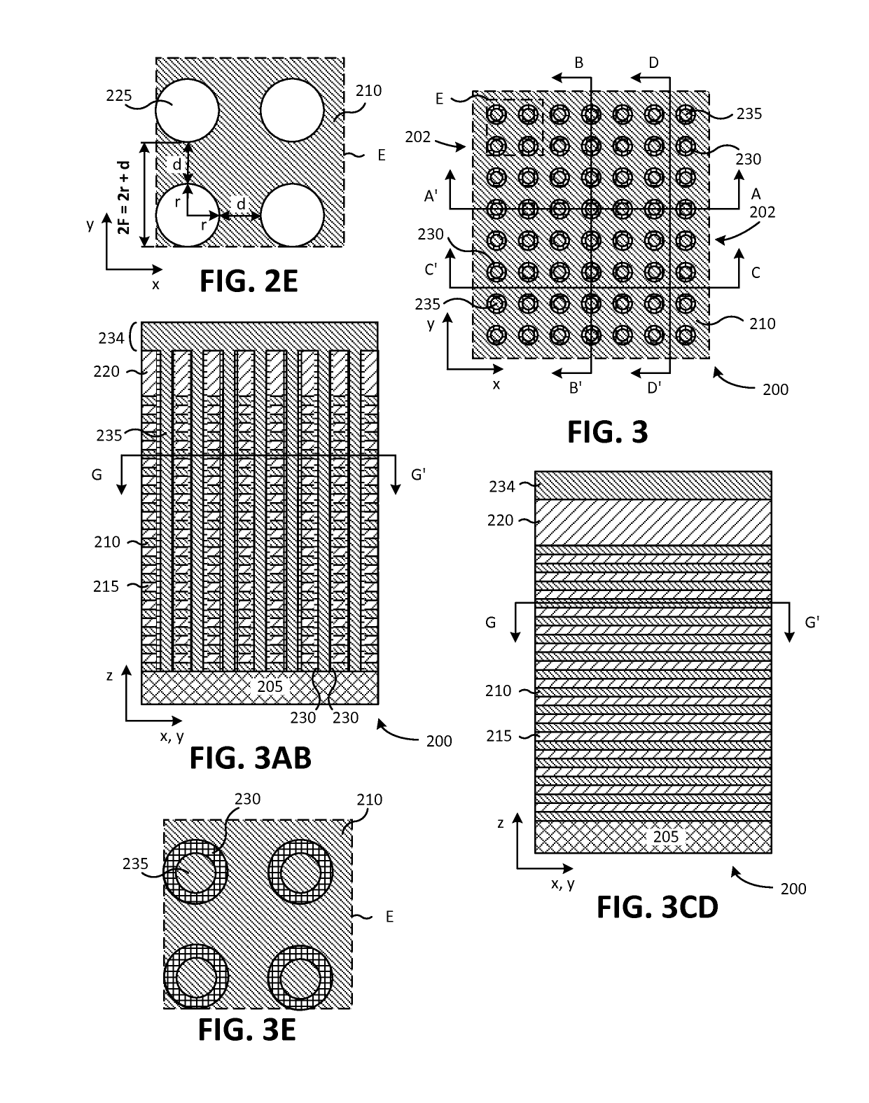

Referring more particularly to the drawings, wherein x-y-z axes may be included as an aid to visualization, FIG. 2 is a top view of a three-dimensional stacked semiconductor structure 200 having a plurality of first holes 225 formed therein. The first holes 225 may be separated from each other and disposed in first rows 202. Typically, the first holes 225 are placed in a regular pattern and, as such, may be disposed in equally-spaced parallel first rows 202. A cross-section of the stacked semiconductor structure 200 of FIG. 2 before formation of first holes 225 may appear as illustrated in FIG. 2CD, which shows a base layer or substrate 205 of material formed of, for example, an oxide or silicon having deposited thereon a plurality of alternating layers of conducting material 210 and insulating material 215. In typical embodiments a number of conducting layers 210 and insulating layers 215 ranging between about 8 pairs and about 256 pairs may be formed on the base layer 205. The conducting layers 210 may be formed of conductive material such as, for example, one or more of polycrystalline silicon (polysilicon), doped polysilicon, single-crystalline silicon, metal silicide, titanium, titanium nitride, tungsten, tungsten nitride, tallium, tallium nitride, platinum and the like. The thickness of the conducting layers 210 may range from about 5 nm to about 500 nm, a typical thickness being about 20 nm. The insulating layers may be formed of, for example, an oxide of silicon such as SiO₂, SiOC, SiOF and the like, and may be deposited with a typical thickness of 30 nm that may range from about 5 nm to about 500 nm. The stack of alternating conducting and insulating layers 210/215 may be overlaid with a layer of insulating material 220, which may be formed of oxide or silicon nitride material to a thickness that may range from about 2 nm to about 1000 nm with a typical thickness of about 50 nm.

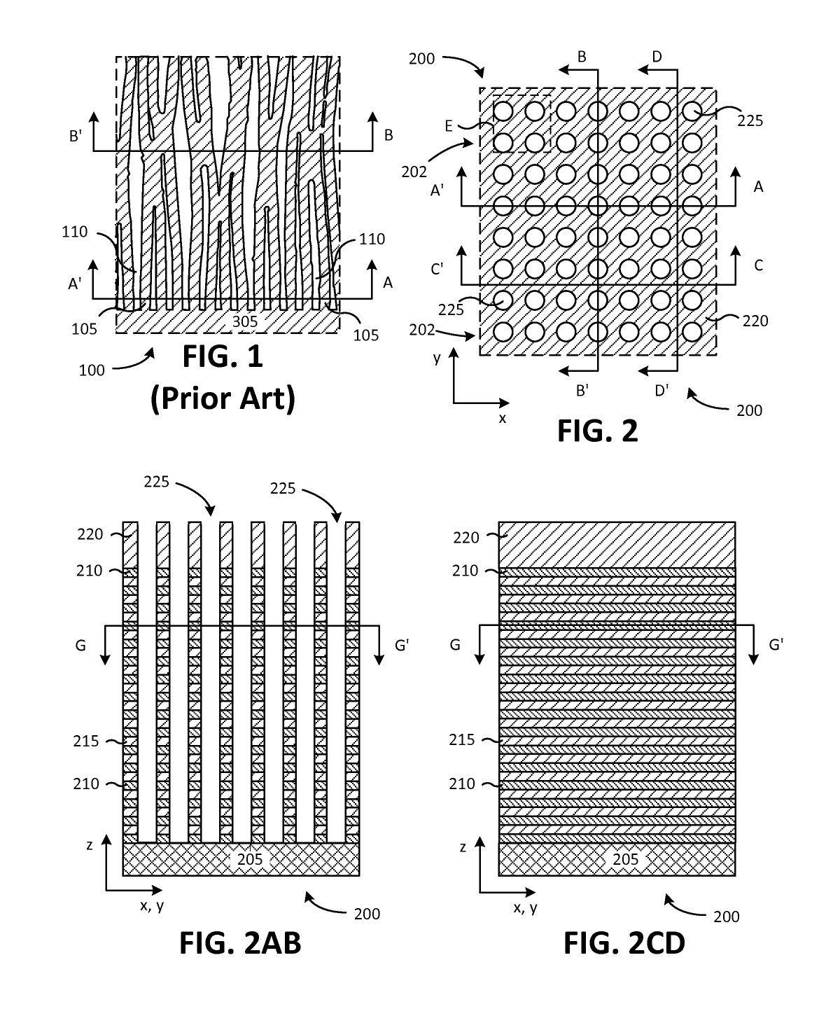

The plurality of first holes 225 may be formed in the semiconductor stack 200 as illustrated in the top view of FIG. 2. According to one example, the first holes 225 are formed by patterning the stack and etching with a dry etch process employing a fluorine-based etchant such as, for example, nitrogen trifluoride (NF₃), and by terminating the etch when the base layer 205 is reached. The first holes 225 may have a circular cross-section with a diameter of about 70 nm, which may be as large as about 200 nm or as small as about 40 nm. A 2D network structure of hole patterns such as those of first holes 225 in FIG. 2 may beneficially prevent or significantly reduce instances of bending and wiggling, issues that have been observed in prior art structures (cf. FIG. 1). The benefit is especially significant when forming holes with high aspect ratios, which may be as large as 20 in some implementations.

FIG. 2AB is a cross-sectional diagram of the structure 200 of FIG. 2 viewed along either/both of orthogonal lines A-A′ and/or B-B′, which pass through the first holes 225, but in orthogonal directions. Similarly, FIG. 2CD is a cross-sectional view of the structure 200 when viewed along either/both of the orthogonal lines C-C′ and/or D-D′, passing between first holes 225 in the structure 200 as shown in FIG. 2.

Detail of a layout of the first holes 225 of FIG. 2 is illustrated in FIG. 2E. The view in FIG. 2E is of a square region identified in FIG. 2 by a dashed box E projected onto an x-y plane of a cross-section G-G′ passing through one of the conducting layers 210 as shown in FIGS. 2AB and 2CD. The regular pattern of the first holes 225 may be based upon, for example, vertices of a rectangle (e.g., a square) or a triangle (e.g., an equilateral triangle). In the present example, the first holes 225 are arranged in a square pattern with each hole 225 having a radius, r, equal to ½ the diameter identified above. The first holes 225 are separated by a distance, d, which may be as small as about 2 nm or as large as about 200 nm, typically about 20 nm. A feature size, F, referring to a lithographic process used to manufacture a memory cell, may be defined in this instance in terms of r and d by a relationship

2F=2r+d.

With the range of values for r and d given above, values for F range from about 20 nm to about 200 nm. A single memory cell, according to the diagram of FIG. 2E, occupies an area of 4F².

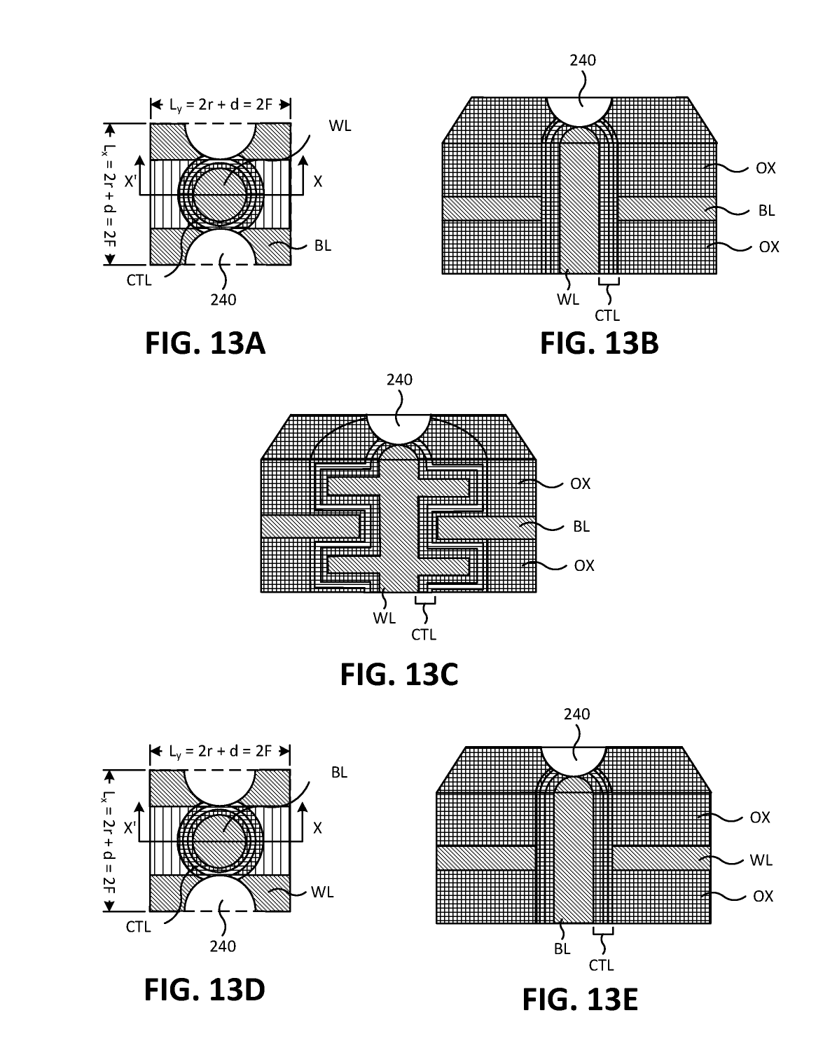

The first holes 225 in the structure of FIG. 2 may be lined with information storage films 230 (see FIG. 3) formed of, for example, oxide-nitride-oxide (ONO) using processes known in the art. According to one example, the ONO films may comprise a tunnel insulation layer and a blocking layer formed of, for example, SiO₂ or a metal oxide. In typical implementations, the tunnel insulation layer connects with a bitline and the blocking layer connects with a wordline. That is, either the inner or the outer oxide layer may be identified as the tunnel insulation layer or the blocking layer, depending upon whether the memory is designed in a vertical gate or vertical channel configuration as described below, for example, with reference to FIGS. 13B, 13C, and 13E. A charge trapping layer formed of, for example, silicon nitride or a metal oxide may be disposed between the tunnel insulation and blocking layers. In another example, the ONO film is formed of a composited oxide-nitride-oxide film.

FIG. 3 is a pictorial representation of a result of deposition of information storage films 230 to line the first holes 225 of the structure of FIG. 2 followed by fill-in of conducting material that may comprise, for example, one or more of the conducting materials introduced above. The conducting material 235, as illustrated in FIG. 3AB in a cross-section taken along either/both of orthogonal lines A-A′ and/or B-B′, fills the lined first holes 225, creating vertical conducting columns 235 of material that are disposed within annular rings formed by the information storage films 230. The fill-in may create an upper layer 234 of conducting material that may cover substantially the entire upper surface of the structure 200, connecting electrically to the conducting columns 235.

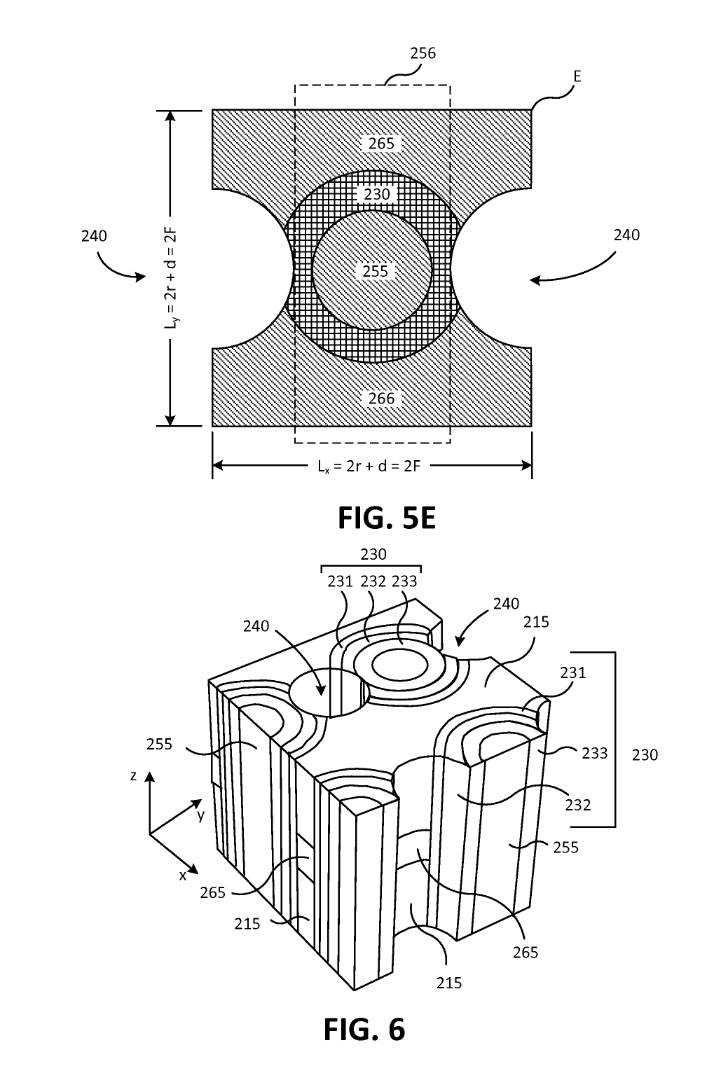

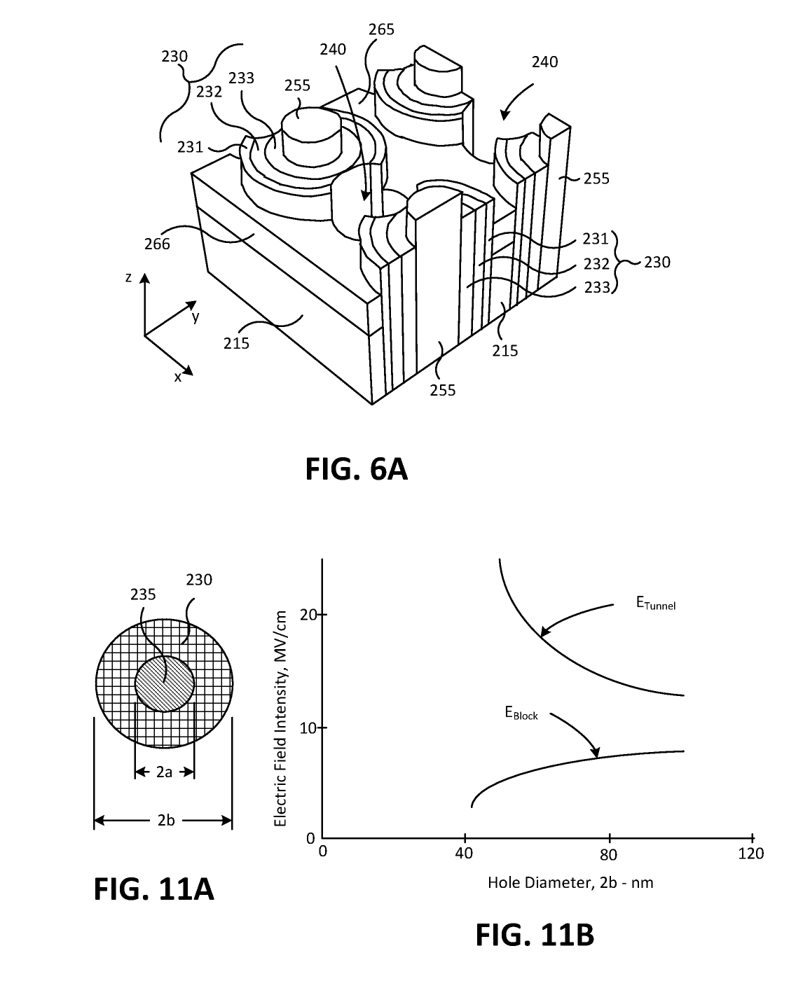

A region identified in FIG. 3 by a dashed box labeled as E is illustrated in FIG. 3E describing detail of an appearance of the first holes 225 lined with information storage films 230 and filled with conducting material (i.e., defining conducting columns 235). The view of FIG. 3E is taken above an x-y plane of a cross-section G-G′ passing through a conducting layer 210 of the structure 200 as illustrated in FIGS. 3AB and 3CD. Although the information storage films, e.g., ONO, films 230 are shown in FIGS. 3, 3AB, and 3E to be uniform in cross-section, the information storage films 230 actually may form a sandwich of oxide [e.g., silicon oxide], nitride [e.g., silicon nitride], and oxide films as illustrated in greater detail with reference to FIGS. 6, 6A and 13A-13D below.

FIG. 3CD is a cross-sectional view of the structure of FIG. 3 taken along either/both lines C-C′ and/or D-D′ showing an alternative between-hole view of the result of fill-in of the first holes 225 with conducting material as well as the upper conducting layer 234.

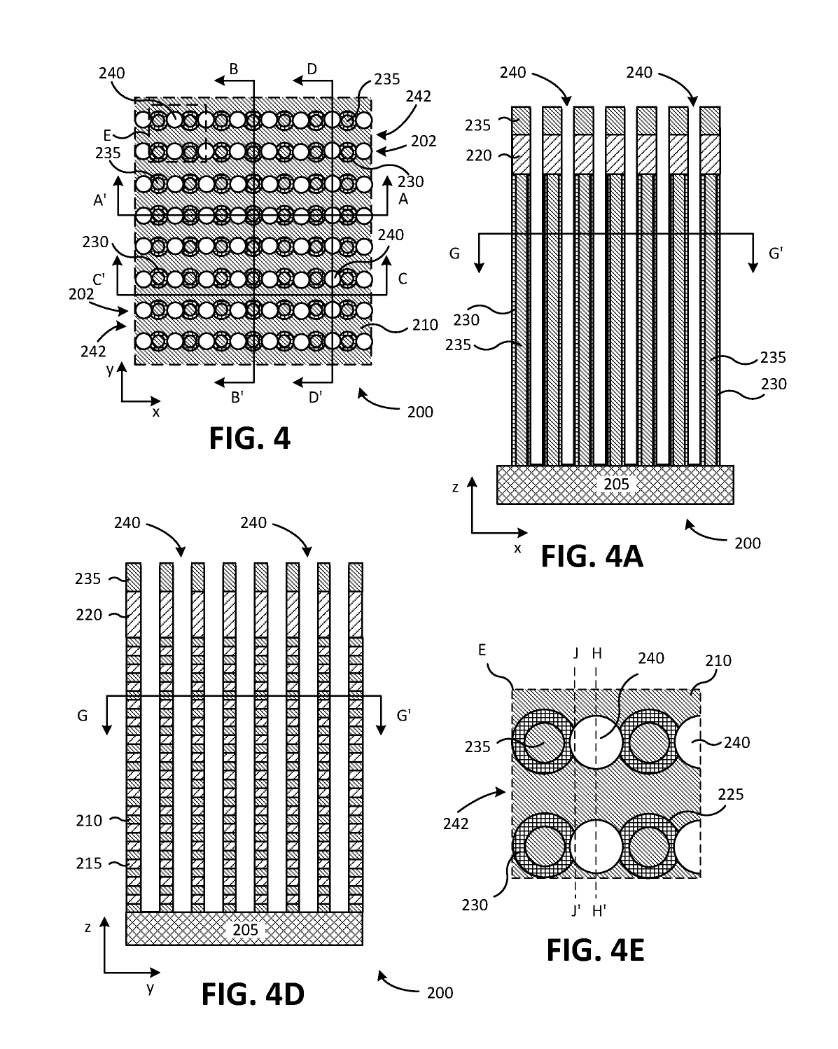

A unit cell of the memory structure 200, is defined by formation of a second plurality of second holes, referred to herein as isolation holes 240, in the structure 200 as illustrated in FIGS. 4, 4A, 4C and 4E. FIG. 4 illustrates such isolation holes 240 distributed in the x-direction in the first rows 202 between the lined and filled-in first holes 225 (FIG. 2) of the structure 200. The isolation holes 240 link adjacent first holes 225 to form a chain comprising a combination of isolation holes 240 and first holes 225 that divides each of the conducting layers 210 into separate strips 242 of conducting material 210. The strips 242 have a varying width determined by the chain of first holes 225 and isolation holes 240. A cross-sectional view of the arrangement of the isolation holes 240 is illustrated in FIG. 4A in a view taken in an x-z plane along the line A-A′ in FIG. 4. A view orthogonal to that of FIG. 4A, shown in FIG. 4D, is taken along the line D-D′ in a y-z plane. The cross-sectional view taken along the line C-C′ is identical to the view shown in FIG. 3CD. Similarly, the cross-sectional view taken along the line B-B′ is identical to the view shown in FIG. 3AB.

Detail of the appearance of the isolation holes 240 is shown in FIG. 4E, which is a view taken in an x-y plane of a cross-section G-G′ normal to the z-axis through a conducting layer 210 in the structure 200 (FIG. 3). The isolation holes 240 are shown to intersect with a portion of the information storage films 230, and the separation of the conducting layer 210 into strips 242 is evident. The arrangement (i.e., relative positions) of the first holes 225 and the isolation holes 240 may have an effect on a critical dimension (CD) (e.g., width) associated with the strips 242 in the conducting layer 210. For example, the CD associated with cross-sections H-H′ and J-J′ in FIG. 4E may be different.

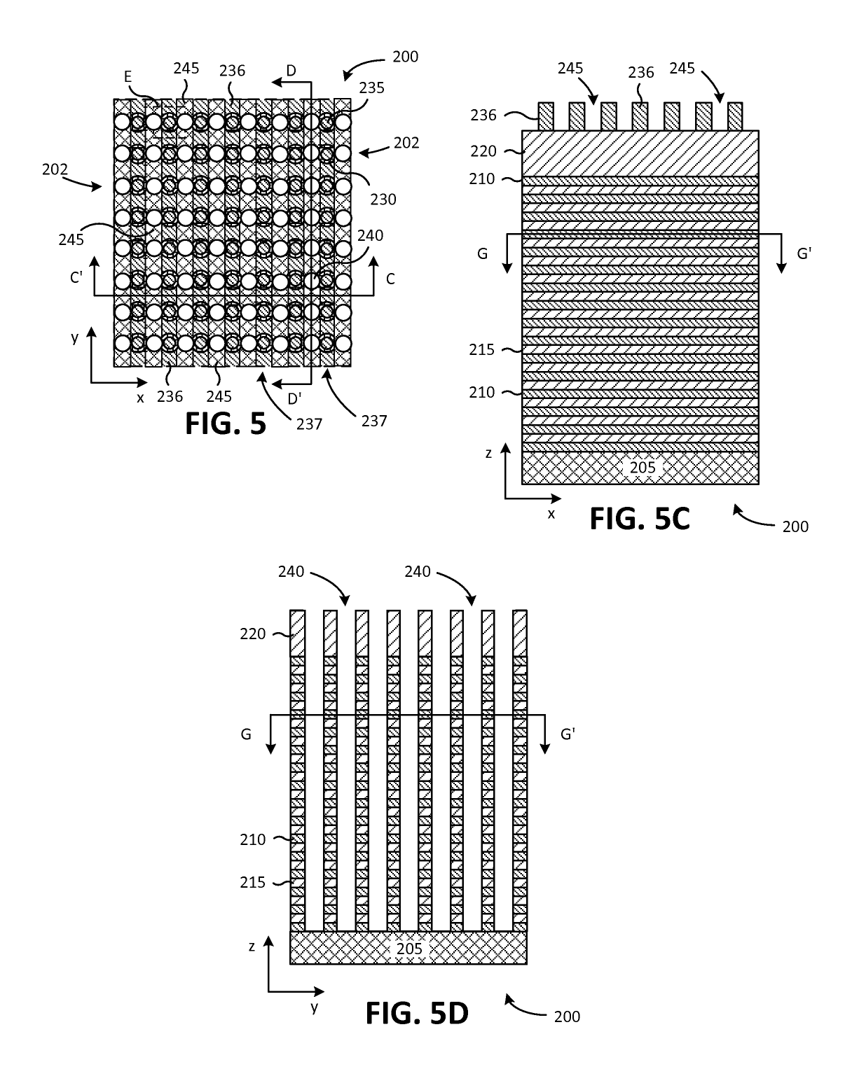

The structure 200 further includes column connectors 236 formed from the upper conducting layer 234 that overlays the insulating layer 220 of the structure 200. The column connectors 236, as shown in FIGS. 5 and 5C, may be formed by a patterning/etching process that creates y-direction-oriented channels 245 in the upper conducting layer 234, effectively defining isolated second rows 237 of conducting columns 235, the second rows 237 extending in a y-direction and crossing the first rows at approximately a right angle. Each of the column connectors 236 connects conducting columns 235 in a given second row 237. Each conducting column 235 extends vertically (i.e., in the z-direction) through the layers 210/215 of the three-dimensional structure 200.

According to one example, a conducting column 235 may perform the function of a wordline in a memory cell. Accordingly, in this same example, the conducting columns 235 may be referred to as wordlines 255 and the column connectors 236 (FIG. 5) may referred to as wordline connectors 256. FIG. 5E illustrates an appearance of such a representative memory cell, e.g., a memory cell located in a layer represented by the region E of a layer in an x-y plane of a cross-section G-G′ of the structure 200 (referring to FIGS. 5, 5C and 5D).

The diagram of FIG. 5E identifies a wordline 255 surrounded by information storage films 230. A projection of a wordline connector 256 onto the cross-section is shown with dashed lines. Isolation holes 240 are also illustrated in FIG. 5E. The conducting material surrounding the information storage films 230 defines bitlines 265 and 266. Bitlines 265 and 266 are isolated from each other by the information storage films 230 and by the isolation holes 240 as already described above with reference to FIG. 4. As before, the dimensions of the unit memory cell are 2F×2F corresponding to an area of 4F².

FIG. 6 provides a perspective view of a portion of a three-dimensional memory device implemented according to the present disclosure. The illustration, a different perspective view of which is repeated in cut-away form in FIG. 6A, illustrates elements already introduced, including insulating layers 215 (cf. FIG. 2CD), bitlines 265 and 266 (cf. FIG. 5E), first holes lined with ONO film layers 231, 232, and 233 that together constitute the information storage film layers 230 (illustrated, for example, in FIG. 5E), wordlines 255 and isolation holes 240.

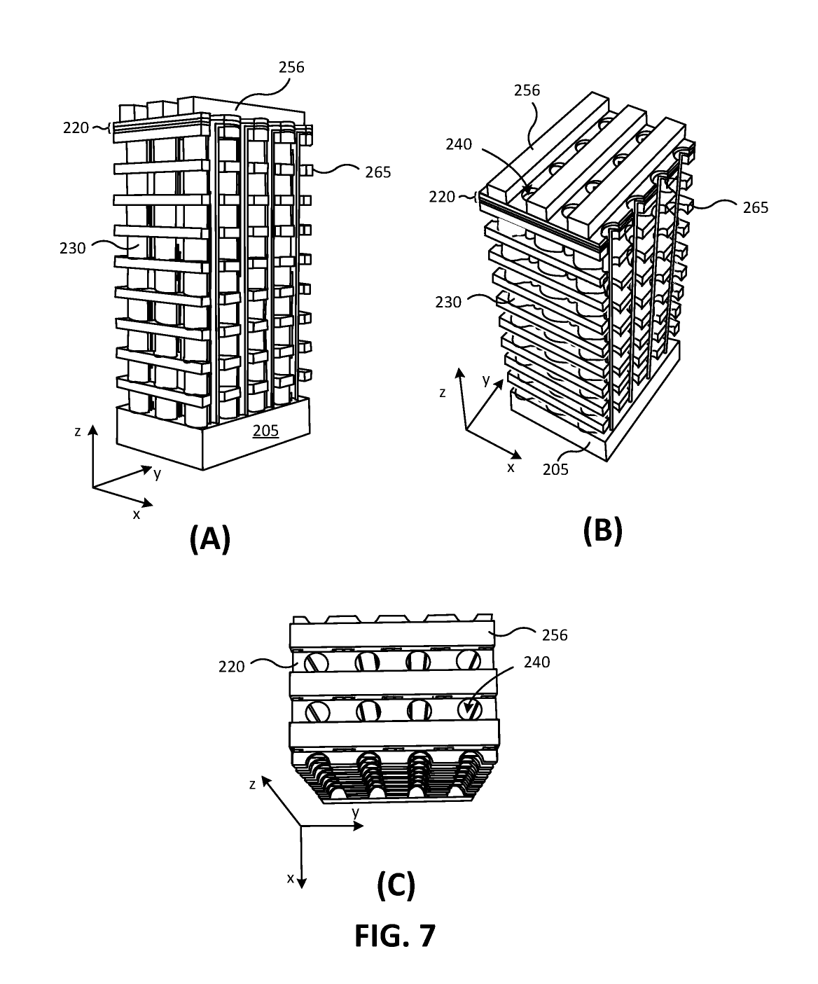

FIG. 7 illustrates sketches of perspective overviews of memory devices contemplated by the present disclosure. The illustrated structures (A), (B), and (C) include wordline connectors 256 (cf. FIG. 5E), isolation holes 240 (cf. FIG. 4) and bitlines 265 (cf. FIG. 5E).

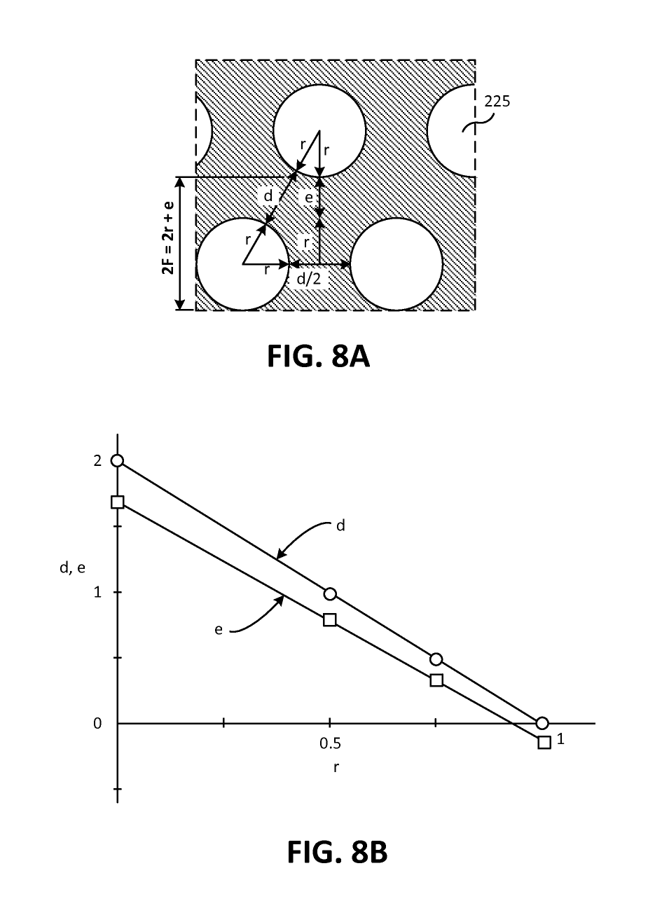

The memory cell architecture just described may be modified to reduce the size of a unit memory cell without reducing the minimum distance between cells. Beginning with the configuration of FIG. 2E, alternate rows of first holes 225 may be shifted in, for example, an x-direction by a distance r+d/2, and the rows 202 (FIG. 2) of first holes 225 may be packed closer together while maintaining the distance between holes at the original value of d. In FIG. 2E, an x-pitch Pₓ may be defined as 2r+d with a y-pitch P_{y} having the same value, given that the layout of the memory cell is configured with first holes 225 arranged according to vertices of a square. In FIG. 8A, Pₓ is unchanged, but P_{y} is reduced to 2r+e where, when the Pythagorean theorem is applied to the dimensions of the elements in FIG. 8A, it becomes clear that

e=(√3−2)×r+(√3/2)×d

or

e=−0.268r+0-0.866d, approximately.

The area of the cell is thus reduced from

(2r+d)²

to

(2r+d)×(2r+e)

so that the ratio of cell areas is

(2r+e)÷(2r+d),

a reduction factor that may be shown to be √3/2 or about 86.6%.

Defining a cell feature dimension, 2F=2r+d, the size of a cell with a square hole placement as presented in FIG. 2E is

2F×2F=4F²,

whereas with efficient hole packing, i.e., by positioning holes according to vertices of an equilateral triangle as shown in FIG. 8A, the cell size is

2F×(√3)F=3.5F², approximately.

Stated alternatively, a density of memory cells per unit volume may be increased by about

2/√3−1

or about 15% with the first hole layout of FIG. 8A when compared with the first hole layout of FIG. 2E.

One example of relationships among r, d, and e is tabulated in TABLE 1 and illustrated as a chart in FIG. 8B.

TABLE 1

| R | d | e | Pₓ | P_{y} | Cell Size | % of 4F² |
|---|---|---|---|---|---|---|
| 0.9 | 0.2 | −0.068 | 2.000 | 1.732 | 3.464 | 86.60 |
| 0.8 | 0.4 | 0.132 | 2.000 | 1.732 | 3.464 | 86.60 |
| 0.7 | 0.6 | 0.332 | 2.000 | 1.732 | 3.464 | 86.60 |
| 0.6 | 0.8 | 0.532 | 2.000 | 1.732 | 3.464 | 86.60 |
| 0.5 | 1.0 | 0.732 | 2.000 | 1.732 | 3.464 | 86.60 |
| 0.4 | 1.2 | 0.932 | 2.000 | 1.732 | 3.464 | 86.60 |
| 0.3 | 1.4 | 1.132 | 2.000 | 1.732 | 3.464 | 86.60 |
| 0.2 | 1.6 | 1.332 | 2.000 | 1.732 | 3.464 | 86.60 |
| 0.1 | 1.8 | 1.521 | 2.000 | 1.732 | 3.464 | 86.60 |

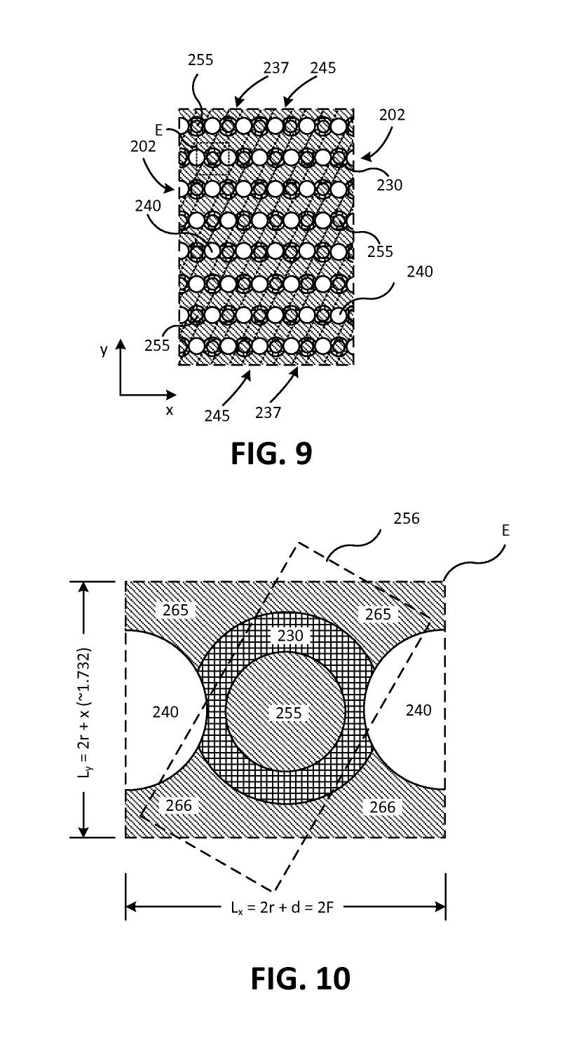

Placement of first holes 225 according to the arrangement shown in FIG. 8A induces a change in the orientation of what are referred to as column connectors 236 in FIG. 5 and identified as wordline connectors 256 in FIG. 5E. FIG. 9 is a modification of FIG. 5 illustrating a change in orientation of alignment of wordline connectors 256 (i.e., column connectors 236 in FIG. 5) according to the modified placement of first holes 225. In the example of FIG. 9, alignment of the wordline connectors 256 is rotated right by 30° relative to the alignment in FIG. 5 so that the wordline connectors 256 define second rows 237 of wordlines 255, the second rows 237 making an angle of about 60° relative to the first rows 202 (FIG. 2). FIG. 10 illustrates the same effect on a smaller scale referring to a region E in FIG. 9. The orientation of a wordline connector 256 is shown in dashed outline in the FIG. 10. The 30° angle of rotation is not intended to be limiting, as other angles of rotation may be employed in some implementations.

Configurations of the first holes 225 illustrated in, for example, FIGS. 2 and 2E may lead to E-field distributions (e.g., tunneling E-field and/or blocking E-field) that are not well suited for use in vertical gate memories, but are well suited for use in vertical channel memories.

FIG. 11B illustrates an example of E-field distributions for a circular hole configuration shown in cross-section in FIG. 11A. The hole, as filled, includes a conducting column 235 surrounded by storage film 230 in a manner previously described above with reference to, for example, FIG. 3E. A diameter of the hole is 2b; a diameter of the conducting column is 2a. In the illustrated example, as described in FIG. 13D below, the conducting column 235 may represent a bit line in a vertical channel memory device, the surrounding storage film 230 may perform charge trapping, and conducting material external to the hole may represent a word line (not explicitly shown in FIG. 11A). In a situation where a voltage on the conducting column 235 is V₀ and the voltage on the word line (i.e., at the outer boundary of the storage film 230) is zero, then the electric field intensity at a point in the storage film at a distance r from the center of the conducting column 235 is given by

$$E ( r ) = \frac{{V}_{0}}{ln ( \frac{b}{a} )} \times \frac{1}{r} .$$

In the present example, it is assumed that V₀=20 V and that the storage film 230 has a thickness of 20 nm so that b=a +20. The electric field intensity at the edge of the conducting column 235, i.e., E(a), may be denoted as E_{Tunnel}; the electric field intensity at the outer edge of the storage film, i.e., E(b), may be denoted as E_{Block}. FIG. 11B illustrates behavior of E_{Tunnel} and E_{Block} plotted with respect to hole diameter, 2b. It may be noted that E_{Tunnel} is enhanced (i.e., increases) as the hole diameter decreases, a property that may favorably influence program/erase properties of a memory device. At the same time, E_{Block} decreases (i.e., is inhibited) with decreasing hole diameter, which may be effective for blocking flow of electrons/holes during program/erase operations.

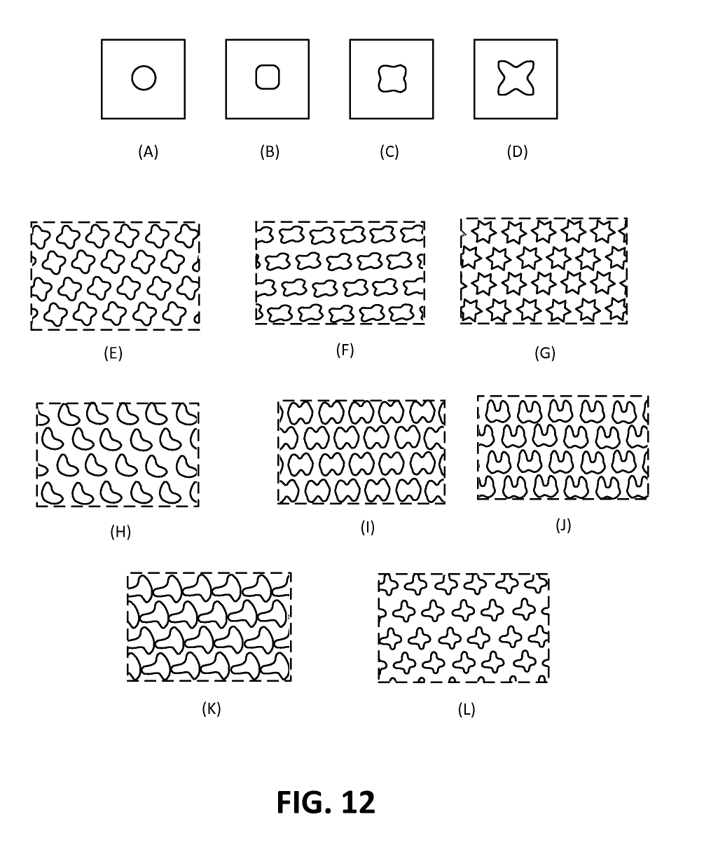

E-field distributions may be altered by choosing alternative shapes for the first holes 225 of FIG. 2. FIG. 12 illustrates an evolution of hole cross-sections beginning with a circular cross-section (A), changing to a square configuration with rounded corners (B), and continuing to an “X” configuration (D). Additional hole shapes are illustrated in (E) through (L). These non-circular hole shapes are intended to be suggestive of the variety of shapes that may be used and are not to be considered as an exhaustive list. E-field distributions associated with the shapes may be evaluated using simulation methods known in the art.

Still more memory device configurations contemplated by the present disclosure are illustrated in FIGS. 13A-13E based upon a canonical cell structure shown in FIG. 13A. The device illustrated in FIG. 13B (which may form, for example, a vertical gate 3D-NAND memory configuration) is based upon the structure 200 described above with reference to, for example, FIG. 5. FIG. 13A identifies insulating layers (OX corresponding to insulating layers 215 in FIG. 5), a bitline layer (BL corresponding to bitline 265 in FIG. 5E), information storage films (ONO corresponding to information storage films 230 in FIG. 5E), a wordline (WL corresponding to wordline 255 in FIG. 5E) and an isolation hole 240. FIG. 13C is similar to FIG. 13B except that the wordline WL is implemented in a finFET-like form. This structure may provide a performance improvement relative to that of the device of FIG. 13B because the wordline WL partially surrounds the bitline BL, which may enhance E-field performance relative to the structure of, for example, FIGS. 13A and 13B.

FIGS. 13D and 13E are identical to respective FIGS. 13A and 13B except that the roles of the wordline (WL) and bitline (BL) are interchanged, thereby forming a vertical channel, not a vertical gate, 3D-NAND memory configuration. This change may resolve E-field issues that may be associated with the vertical gate structure.

Referring again to FIG. 11B and comparing with FIGS. 13D and 13E, the vertical conducting column 235 (FIG. 11A) functions as a bitline in a vertical channel structure. This means that the tunnel oxide is next to the bitline while the blocking oxide is adjacent to the wordline. As seen in FIG. 11B, this arrangement beneficially affects E-field enhancement (i.e., higher E-field on tunnel oxide; lower E-field on blocking oxide) that may favorably affect device performance as hole diameter decreases. In contrast, when the vertical conducting column 235 becomes a wordline as in the vertical gate structure of FIGS. 13A and 13B, the structure exhibits the opposite E-field enhancement, as the tunnel oxide is next to the bitline and the blocking oxide is next to the wordline. That is, in the vertical gate arrangement, E_{Tunnel} decreases while E_{Block} increases with decreasing hole diameter.

E-field enhancement may be observed in both the vertical channel and vertical gate structures when an X-shaped hole profile and/or a finFET-like structure is employed.

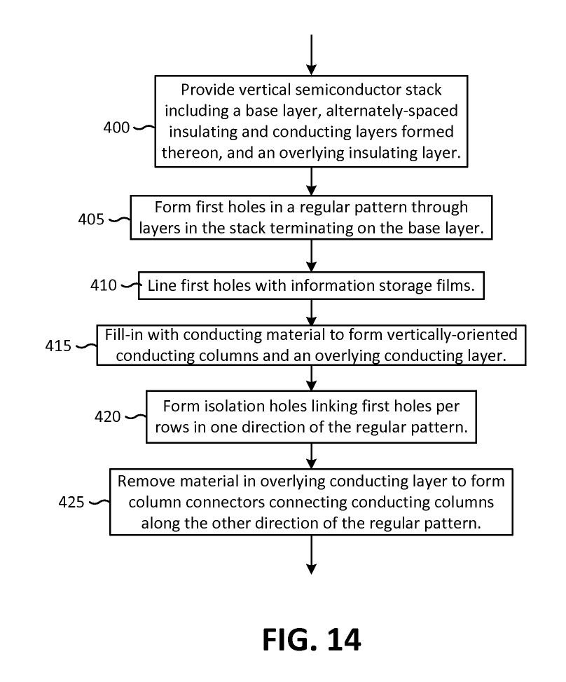

Fabrication of memory devices of the type disclosed herein may be achieved by employing a method of the present disclosure. One implementation of the method is summarized in the flowchart of FIG. 14. According to the illustrated implementation, a vertical semiconductor stack is provided at step 400. The stack includes a base layer with alternately-spaced insulating and conducting layers formed thereon and an overlying insulating layer. FIG. 2CD illustrates a cross-section of such a stack 200. A base layer 205, which may comprise, for example, silicon is overlaid with alternating conducting layers 210 and insulating layers 215. An insulating layer 220 overlays the alternating conducting and insulating layers 210/215.

Holes, which may be referred to as first holes, are formed in the stack at step 405. The first holes may be arranged in a regular pattern according to, e.g., corners of a square. Alternatively, the arrangement of the first holes may take other forms with the description of FIG. 8A referenced above being one example. FIG. 2 illustrates a top view of first holes 225 placed in a square arrangement. The first holes 225 may be formed by patterning and etching the provided semiconductor stack with an anisotropic etchant, the etching terminating on the base layer 205. This forming of holes advantageously avoids bending and wiggling issues associated with creation of lines and/or trenches having high aspect ratios according to prior art methods. Vertical stringers (parasitic connections between conducting layers) also are not formed by this process.

At step 410 the first holes may be lined with information storage films. The information storage films may comprise oxide-nitride-oxide (ONO) layers known in the art. Detail of the position and arrangement of the information storage films is shown in FIG. 3E, which identifies such films 230. Further detail of an embodiment of information storage films is illustrated in FIGS. 6 and 6A which point out charge-trapping layers (e.g. oxide/nitride/oxide films 231/232/233) identified separately. Other illustrations of charge-trapping layers (CTL), which may comprise ONO films, are shown in FIGS. 13A-13D. In other examples, the CTL may comprise a multilayer dielectric charge trapping structure.

The lined first holes are filled-in with conducting material at step 415 thereby forming vertical columns of conducting material that may be referred to as conducting columns. The fill-in may include formation of an overlying conducting layer that electrically connects the conducting columns together. A diagram showing an appearance of one of the conducting layers 210 after fill-in of the conducting material at step 415 appears in FIG. 3. It may be noted that the layer 210 appears to nearly completely comprise conducting material except that annular rings of information storage film 230 associated with each of the first holes 225 (FIG. 2) separate the conducting columns 235 (i.e., the filled-in conducting material) from the conducting material 210 in the original layers. This condition is described in detail in FIG. 3E showing a top view of conducting columns 235 surrounded by information storage films 230 disposed in the conducting layer 210. A cross-section taken along either/both of the lines A-A′ and/or B-B′ in FIG. 3 is shown in FIG. 3AB. The figure illustrates conducting columns 235 interleaved with narrow stacks of alternating conducting and insulating material 210/215 and separated therefrom by cylindrical rings of information storage films 230.

Isolation holes are formed in the stack at step 420 with the isolation holes being placed between the filled-in first holes in one direction of the regular arrangement. The isolation holes are positioned to intrude on, i.e., remove part of, the information storage films and to separate regions of conducting material in the original conducting layers. FIG. 4 illustrates placement of isolation holes 240. The isolation holes 240 may be formed by patterning the structure of FIG. 3 and using an anisotropic dry etch process to form holes that reach the base layer 205. Cross-sectional views of the isolation holes 240 are shown in FIGS. 4A and 4D, which describe appearances of the isolation holes 240 taken along respective lines A-A′ and D-D′ in FIG. 4. FIG. 4E describes the appearance of the isolation holes 240 in detail according to the illustrated embodiment. Placement of the first holes 225 (FIG. 2) and the isolation holes 240 effectively converts each of the conducting layers 210 (cf. FIG. 3CD) into a collection of separate conducting elements shown as irregular strips 242 in FIG. 4. As shown in FIGS. 6 and 10, these separate conducting elements may be employed as bitlines 265/266 in one embodiment of a three-dimensional memory structure.

Finally, material in the overlying conducting later may be removed at step 425 in order to provide separate conducting paths between conducting columns in a direction that makes an angle (e.g., a right angle) with the first rows 202 of first holes 225 and isolation holes 240. Referring specifically to FIG. 5 as an example, a portion of remaining parts of the overlying conducting layer 234 (FIG. 3CD) may be removed by patterning and etching, leaving strips of conducting material that connect conducting columns 235 and therefore may be designated as column connectors 236. Alternatively, when a different arrangement is chosen for the first holes 225 as indicated in FIGS. 9 and 10, then the first rows 237 of column connectors 236 (e.g., wordline connectors 256) may appear at a different angle with respect to the first rows 202 of first holes 225 and isolation holes 240. The functionality of the three-dimensional memory structure is not changed by this placement of first holes 225, and the density of memory elements may be increased by about 15% as already described above.

As an optional step (not illustrated in FIG. 14) the isolation holes may be filled with dielectric material such as an oxide or low-k material. In some examples, device properties may be improved by not filling the isolation holes, thereby implementing an air gap.

Whereas the apparatus disclosed herein may provide a three-dimensional NAND memory structure, the method disclosed may also be applied to the manufacture of such non-volatile memory devices.

Although the disclosure herein refers to certain illustrated embodiments, it is to be understood that these embodiments have been presented by way of example rather than limitation. The intent accompanying this disclosure is to have such embodiments construed in conjunction with the knowledge of one skilled in the art to cover all modifications, variations, combinations, permutations, omissions, substitutions, alternatives, and equivalents of the embodiments, to the extent not mutually exclusive, as may fall within the spirit and scope of the invention as limited only by the appended claims.

What is claimed is:

1. A three-dimensional semiconductor memory device comprising:
a plurality of alternating layers of conducting material and insulating material overlying a substrate;
a plurality of first holes in the alternating layers disposed in first rows, wherein:
the first holes are lined with information storage film; and
the lined first holes are filled with conducting material that forms conducting columns;
a plurality of isolation holes disposed in the alternating layers between and linking adjacent first holes in the first rows; and
a plurality of column connectors that connect conducting columns in second rows, wherein the second rows cross the first rows at an angle.

2. The three-dimensional semiconductor memory device as set forth in claim 1, wherein:
the first rows are parallel; and
the angle not a right angle.

3. The three-dimensional semiconductor memory device as set forth in claim 2, wherein a memory cell in the semiconductor memory device having an angle of about 60° is about 86.6% of the size of a memory cell in the semiconductor device having an angle of about 90°.

4. The three-dimensional semiconductor memory device as set forth in claim 1, wherein the conducting columns comprise wordlines defining a vertical gate memory device.

5. The three-dimensional semiconductor memory device as set forth in claim 4, wherein a form of the conducting columns is modified to create a finFET-like vertical gate memory device.

6. The three-dimensional semiconductor memory device as set forth in claim 1, wherein the conducting columns comprise bitlines defining a vertical channel memory device.

7. The three-dimensional semiconductor memory device as set forth in claim 1, wherein:
the layers of conducting material comprise one or more of polycrystalline silicon, doped polycrystalline silicon, single-crystalline silicon, metal silicide, titanium, titanium nitride, tungsten, tungsten nitride, tallium, tallium nitride, and platinum; and
the layers of insulating material comprise one or more of SiO₂, doped oxide, SiOC, silicon nitride, SiON, SiOF, or metal oxide.

8. The three-dimensional semiconductor memory device as set forth in claim 1, wherein the first plurality of holes have a circular cross-section.

9. The three-dimensional semiconductor memory device as set forth in claim 1, wherein the first plurality of holes have a cross-section that is not circular.

10. A method, comprising:
providing a vertical semiconductor stack comprising alternately-spaced insulating and conducting layers formed above a base layer;
forming a plurality of first holes in the alternating layers, the first holes being disposed in an arrangement based on a regular pattern;
lining the first holes with information storage films;
filling-in the lined first holes with conducting material to form conducting columns;
forming an overlying conducting layer connected to the conducting columns;
disposing isolation holes between adjacent first holes in first rows, the isolation holes linking with the first holes;
removing portions of the overlying conducting layer to form column connectors connecting conducting columns in second rows that form an angle with the first rows.

11. The method as set forth in claim 10, wherein:
the forming of the first holes comprises disposing the first holes in a regular pattern based upon corners of a square; and
the removing comprises forming column connectors connecting columns in second rows that form an angle of about 90° with the first rows.

12. The method as set forth in claim 10, wherein:
the forming of the first holes comprises disposing the first holes in a regular pattern based upon vertices of an equilateral triangle; and
the removing comprises forming column connectors connecting columns in second rows that form an angle of about 60° with the first rows.

13. The method as set forth in claim 10, wherein:
the lining comprises forming liners in the first holes, the liners comprising multilayer dielectric charge-trapping structures; and
the filling-in comprises disposing conducting material comprising one or more of polycrystalline silicon, doped polycrystalline silicon, single-crystalline silicon, metal silicide, titanium, titanium nitride, tungsten, tungsten nitride, tallium, tallium nitride, and platinum into the lined first holes, thereby filling the holes.

14. A semiconductor memory device comprising:
parallel rows of stacks of alternating layers of conducting material and insulating material;
parallel rows of columns connected with and separating the parallel rows of stacks, wherein:
the rows of columns comprise alternating first columns and second columns linked together;
the first columns comprise outer layers of information storage films and inner cores of conducting material that forms conducting columns separated by the second columns; and
rows of conducting material that overlie the conducting columns and are connected to conducting columns in rows that form an angle with the parallel rows.

15. The semiconductor memory device as set forth in claim 14, wherein:
the parallel rows of stacks of conducting material form bitlines;
the conducting columns form wordlines; and
the semiconductor memory device is a vertical gate memory device.

16. The semiconductor memory device as set forth in claim 14, wherein:
the parallel rows of stacks of conducting material form wordlines;
the conducting columns form bitlines; and
the semiconductor memory device is a vertical channel memory device.

17. The semiconductor memory device as set forth in claim 14, wherein:
the conducting material comprises one or more of polycrystalline silicon, doped polycrystalline silicon, single-crystalline silicon, metal silicide, titanium, titanium nitride, tungsten, tungsten nitride, tallium, tallium nitride, and platinum; and
the insulating material comprises one or more of SiO₂, doped oxide, SiOC, silicon nitride, SiON, SiOF, and metal oxide.

18. The semiconductor memory device as set forth in claim 14, wherein the angle is not a right angle.

19. The semiconductor memory device as set forth in claim 14, wherein the information storage films comprise a tunnel layer, a charge trapping layer, and a blocking layer.

20. The semiconductor memory device as set forth in claim 19, wherein:
the tunnel layer comprises one or more of an oxide of silicon and a metal oxide;
the blocking layer comprises one or more of an oxide of silicon and a metal oxide; and
the charge trapping layer comprises one or more of silicon nitride and a metal oxide.
